(19) United States
(12) Patent Application Publication
(10) Pub. No.: US 2026/0190709 A1
(43) Pub. Date: Jul. 2, 2026

(54) DISPLAY DEVICE

(71) Applicant: LG Display Co., Ltd., Seoul (KR)

(72) Inventors: Kyu-Hwang Lee, Paju-si (KR); Jungho Bang, Paju-si (KR); Dongkyu Lee, Goyang-si (KR); Munchan Kang, Goyang-si (KR)

(73) Assignee: LG Display Co., Ltd., Seoul (KR)

(21) Appl. No.: 19/394,762

(22) Filed: Nov. 19, 2025

(30) Foreign Application Priority Data
Dec. 26, 2024 (KR) 10-2024-0197746

(51) Int. Cl. H10K 59/131; H10K 59/40; H10K 77/10

(52) U.S. Cl. CPC H10K 59/131; H10K 59/40; H10K 77/111

(57) ABSTRACT

Disclosed is a display device including a substrate including a display area and a non-display area outside the display area, the non-display area including a link area and a bendable area; a plurality of signal link lines in the link area of the substrate, the link area being between the display area and the bendable area; a plurality of connection lines electrically connected respectively to the plurality of signal link lines in the link area and extending to the bendable area; an organic insulating layer above and spaced apart from the plurality of connection lines; an optical layer over the organic insulating layer in the link area; and a bending protective layer in contact with an end of the optical layer in the link area and extending to the bendable area, wherein the organic insulating layer includes a broken region in the link area.

### CROSS REFERENCE TO RELATED APPLICATION

The present application claims priority to Korean Patent Application No. 10-2024-0197746, filed Dec. 26, 2024, the entire contents of which is incorporated herein for all purposes by this reference.

### BACKGROUND

### Field

The present disclosure relates to a display device.

### Description of Related Art

A display device is applied to various electronic devices, such as a TV, a smartphone, a laptop, and a tablet. To this end, research is being conducted for thinness, lighter weight, low power consumption, and the like for display devices.

Examples of the display devices may include, among others, a liquid crystal display (LCD) device, a field emission display (FED) device, an organic light-emitting display (OLED) device, and the like.

A bezel area of the display device may be visually recognized by a user and may be a factor that degrades a sense of immersion in an image emitted from a display area. Accordingly, recently, there is an increasing demand for a display device implementing a narrow bezel with a reduced bezel area where an image is not displayed or implementing a zero bezel that substantially has an effect of not having a bezel area.

### SUMMARY

As a flexible substrate made of a flexible material is applied to a display device, a display panel may include a bendable area that bends to hide a pad area under a display area. Accordingly, a bezel area of the display device visually recognized by a user may be reduced.

The bendable area may include multiple connection lines to transmit various signals to pixels on the display area, and the multiple connection lines may be connected to signal lines in a link area adjacent to the display area.

However, if an organic insulating material is exposed in a non-display area adjacent to the bendable area because of an external impact or the like, moisture may penetrate into the display area via the organic insulating material. When moisture penetrates, a line including a metal material, such as the connection line or the signal line, may be electrolytically corroded or corroded.

Accordingly, through various experiments, the inventors of the present disclosure have invented a display device capable of preventing or suppressing moisture from penetrating into an area of the line(s) including a metal material via the organic insulating material on the non-display area adjacent to the bendable area.

A purpose of one or more embodiments of the present disclosure is to provide a display device capable of preventing or protecting a line including a metal material from being damaged by moisture penetration.

Another purpose of one or more embodiments of the present disclosure is to provide a display device capable of preventing or suppressing damage to a connection line or a signal link line caused by moisture penetration via an organic insulating material in a contact hole in a non-display area adjacent to a bendable area.

Purposes according to various embodiments of the present disclosure are not limited to the above-mentioned purposes. Other purposes and advantages according to the present disclosure that are not mentioned may be understood based on following descriptions, and may be more clearly understood based on example embodiments of the present disclosure. Further, it can be easily understood from the descriptions provided herein that the purposes and advantages according to various example embodiments of the present disclosure may be realized by practicing the example embodiments described herein, including in the claims or combinations thereof.

To achieve these objects and other advantages and in accordance with purposes of the present disclosure, as embodied and broadly described herein, a display device according to an embodiment of the present disclosure includes a substrate including a display area and a non-display area outside the display area, the non-display area including a link area and a bendable area; a plurality of signal link lines in the link area of the substrate, the link area being between the display area and the bendable area; a plurality of connection lines electrically connected respectively to the plurality of signal link lines in the link area and extending to the bendable area; an organic insulating layer above and spaced apart from the plurality of connection lines; an optical layer over the organic insulating layer in the link area; and a bending protective layer in contact with an end of the optical layer in the link area and extending to the bendable area, wherein the organic insulating layer includes a broken region in the link area.

In another aspect, a display device according to an embodiment of the present disclosure includes a substrate including a display area including a pixel, and a non-display area outside the display area, the non-display area including a bendable area and including a link area between the display area and the bendable area; a data link line in the link area of the substrate for transmitting a signal or voltage to the pixel in the display area; a first connection line electrically connected to the data link line in the link area and extending to the bendable area; an inorganic insulating layer on the first connection line; an organic insulating layer on the inorganic insulating layer and spaced apart from the first connection line; and an optical layer over the organic insulating layer and having a distal end in the link area, wherein the organic insulating layer includes a discontinuous part in the link area.

According to one or more embodiments of the present disclosure, as at least one broken region or discontinuous part (for example, an opening or a distal end) is included in the organic insulating layer in the link area such that the organic insulating layer does not have the continuity in the link area adjacent to the bendable area of the non-display area, external moisture may be prevented or blocked from contacting the connection line.

According to one or more embodiments of the present disclosure, the organic insulating material layer may be disconnected via an opening extending through the organic insulating material layer disposed on the non-display area between the display area and the bendable area, thereby blocking the moisture penetration path through which moisture may penetrate.

Accordingly, the organic insulating material may be prevented or suppressed from becoming the moisture penetration path, so that the potential defect due to the connection line or the signal line being exposed to moisture and being damaged may be prevented or suppressed from occurring. Accordingly, the signal(s) or the voltage(s) for operating the display area may be stably provided, thereby improving the product reliability.

According to one or more embodiments of the present disclosure, because the defect rate of the display device resulting from the corrosion of the connection lines or the signal lines may be lowered, the production energy required for the further production of the display devices may be reduced, thereby reducing the emission of greenhouse gas.

Effects of the present disclosure are not limited to the effects mentioned above, and other effects not mentioned may be clearly understood by those skilled in the art from the description as set forth below.

In addition to the above effects, specific effects of the present disclosure are described together in, or may be understood from, the description of specific details for implementing the example embodiments of the present disclosure detailed below.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain the principles of the disclosure.

FIG. 1 is a plan view of a display panel according to example embodiments of the present disclosure.

FIG. 2 is a cross-sectional view taken along a line I-I′ in FIG. 1.

FIG. 3 is an enlarged view of an area II in FIG. 1.

FIG. 4 is a cross-sectional view taken along a line III-III′ in FIG. 3.

FIG. 5 is a cross-sectional view taken along a line IV-IV′ in FIG. 3.

FIG. 6 is a plan view according to other example embodiments of the present disclosure.

FIGS. 7 and 8 are cross-sectional views according to another example embodiment of the present disclosure, taken respectively along lines III-III′ and IV-IV′ in FIG. 6.

FIGS. 9 to 11 are cross-sectional views according to still another example embodiment of the present disclosure.

FIGS. 12 and 13 are cross-sectional views according to yet other example embodiments of the present disclosure.

### DETAILED DESCRIPTION

Advantages and features of the present disclosure, and a method of achieving the advantages and features will become apparent with reference to example embodiments described below in detail together with the accompanying drawings. However, the present disclosure is not limited to the example embodiments as disclosed below but may be implemented in various other forms. Thus, these embodiments are set forth only to make the present disclosure more complete, and to more fully inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality, unless otherwise specified. Further, descriptions and details of well-known steps and elements may be omitted for simplicity of the description. Furthermore, in the following detailed description of example embodiments of the present disclosure, numerous specific details may be set forth to provide a thorough understanding of the present disclosure. However, it should be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It should be understood that the description herein is not intended to limit the claims to the specific embodiments described. On the contrary, it is intended to cover alternatives, modifications, and equivalents as may be included within the spirit and scope of the present disclosure as defined by the appended claims and their equivalents.

A shape, a size, a ratio, an angle, a number, etc., disclosed in the drawings for illustrating example embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It should be further understood that the terms “comprise,” “comprising,” “include,” and “including,” where used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expressions like “at least one of,” where preceding a list of elements, may modify the entire list of elements and may not modify the individual elements of the list. In interpretation of numerical values, an error or tolerance therein may occur even where there is no explicit description thereof.

In addition, it should also be understood that when a first element or layer is referred to as being present “on” a second element or layer, the first element may be disposed directly on the second element or may be disposed indirectly on the second element with a third element or layer being disposed between the first and second elements or layers. It should be understood that, where an element or layer is referred to as being “connected to,” or “coupled to” another element or layer, it may be directly connected to or coupled to the other element or layer, or one or more intervening elements or layers may be present therebetween. In addition, it should also be understood that, where an element or layer is referred to as being “between” two elements or layers, it may be the only element or layer between the two elements or layers, or one or more intervening elements or layers may also be present.

Further, as used herein, where a layer, film, area, plate, or the like is described as being disposed “on” or “on top” of another layer, film, area, plate, or the like, the former may directly contact the latter or still another layer, film, area, plate, or the like may be disposed between the former and the latter. As used herein, where a layer, film, area, plate, or the like is described as being directly disposed “on” or “on top” of another layer, film, area, plate, or the like, the former directly contacts the latter and still another layer, film, area, plate, or the like is not disposed between the former and the latter. Further, as used herein, where a layer, film, area, plate, or the like is described as being disposed “beneath” or “under” another layer, film, area, plate, or the like, the former may directly contact the latter or still another layer, film, area, plate, or the like may be disposed between the former and the latter. As used herein, where a layer, film, area, plate, or the like is described as being directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless a more limiting phrase like “directly after,” “directly subsequent,” or “directly before” is indicated.

Where a certain embodiment may be implemented differently, a function or an operation specified in a specific block may occur in a different order from an order specified in a flowchart. For example, two blocks in succession may be actually performed substantially concurrently, or the two blocks may be performed in a reverse order, depending on a function or operation involved.

It should be understood that, although the terms “first,” “second,” “third,” and so on may be used herein to describe various elements, components, areas, layers, and/or periods, these elements, components, areas, layers, and/or periods should not be limited by these terms. These terms are used to refer to one element, component, area, layer, or period separately from another element, component, area, layer, or period. Thus, a first element, component, area, layer, or period as described herein could be termed a second element, component, area, layer, or period, and vice versa, without departing from the spirit and scope of the present disclosure.

The features of the various embodiments of the present disclosure may be partially or entirely combined with each other, and may be technically associated with each other or operate with each other. The embodiments may be implemented independently of each other or may be implemented together in an association relationship.

In interpreting a numerical value, the value is to be interpreted as including an error range unless otherwise specified.

Unless otherwise defined, all terms including technical and scientific terms used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term “or” means “inclusive or” rather than “exclusive or.” That is, unless otherwise stated or clear from the context, the expression that “x uses a or b” means one of natural inclusive permutations.

The terms used in the description below have been selected as being general and universal in the related technical field. However, there may be other terms that are equivalent, similar, or appropriate depending on the development and/or change of technology, convention, preference of technicians, etc. Therefore, the terms used in the description below should not be understood as limiting technical ideas but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Description.

In description of flow of a signal, for example, where a signal is described as being delivered from a node A to a node B, this may include a case where the signal is transferred from the node A to the node B via another node unless a more limiting phrase like “immediately transferred” or “directly transferred” is used.

Throughout the present disclosure, if used, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components encompasses not only a first, second, or third component individually, but also all combinations of two or more of the first, second, and third components.

Hereinafter, example embodiments of the present disclosure will be described with reference to the attached drawings. A scale of each of components as shown in the drawings may be different from an actual scale thereof for convenience of illustration. Therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to example embodiments of the present disclosure will be described with reference to the drawings.

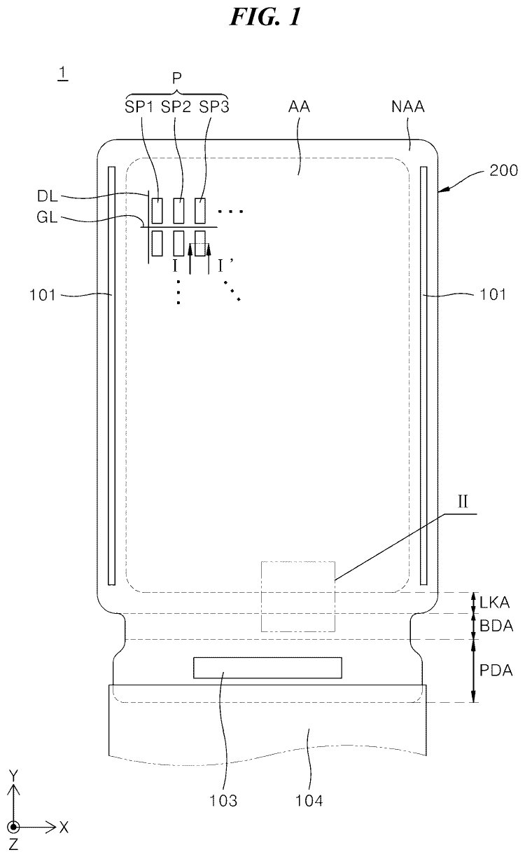

FIG. 1 is a plan view of a display panel according to example embodiments of the present disclosure.

As illustrated in FIG. 1, a display device according to example embodiments of the present disclosure may include a display panel 200, a gate driver 101, a data driver 103, a flexible printed circuit board 104, and the like.

The display panel 200 may include a display area AA and a non-display area NAA. The display area AA may be an area in which an image is displayed. The non-display area NAA may be an area in which no image is displayed. The non-display area NAA may be located in a peripheral area (or an edge area) of the display panel 200 but may not be limited thereto. For example, a remaining area except for a light emissive area in which light is emitted to the outside on the display area AA may be referred to as the non-display area NAA. A bezel area of the display device may be defined by the non-display area NAA. The bezel area may surround an outer side of the display area AA. A link area LKA, a bendable area BDA, and a pad area PDA may be disposed at a lower end of the non-display area NAA.

A plurality of pixels P may be disposed in the display area AA. One pixel P may be composed of a plurality of sub-pixels SP1, SP2, and SP3. The image may be displayed in the display area AA via the plurality of sub-pixels SP1, SP2, and SP3. The plurality of sub-pixels SP1, SP2, and SP3 may be arranged in an array on the display area AA. In an example, the plurality of sub-pixels SP1, SP2, and SP3 may be arranged in a matrix array by being spaced apart from each other in a first direction and a second direction intersecting the first direction of the display area AA. The first direction may be a horizontal direction, an X-axis direction, or a row direction, and the second direction may be a vertical direction, a Y-axis direction, or a column direction. However, the present disclosure may not be limited thereto, and an arrangement shape, an arrangement order, and an arrangement direction of the sub-pixels SP1, SP2, and SP3 may be variously changed.

The display area AA includes a plurality of data lines DL and a plurality of gate lines GL arranged to intersect each other. For example, one sub-pixel may be defined where one data line DL and one gate line GL intersect each other. The data line DL may transmit a data signal generated by the data driver 103 to the sub-pixel, and the gate line GL may transmit a gate signal generated by the gate driver 101 to the sub-pixel. The gate lines GL may extend in the first direction (X) of the display panel 200, and the data lines DL may intersect the gate lines GL and extend in the second direction (Y) of the display panel 200.

Here, one pixel P is described as being composed of the first sub-pixel SP1, the second sub-pixel SP2, and the third sub-pixel SP3 as an example embodiment, but the present disclosure is not limited thereto. For example, one pixel P may further include one or more additional sub-pixels.

The sub-pixels SP1, SP2, and SP3 may be implemented to emit light of the same color, such as white light, or may be implemented to emit light of different colors, such as red, green, or blue light. For example, the first sub-pixel SP1 may render red, the second sub-pixel SP2 may render green, and the third sub-pixel SP3 may render blue.

Various wirings, circuits, and the like for driving the plurality of sub-pixels SP of the display area AA may be disposed in the non-display area NAA. For example, driving circuits including a gate driving circuit and a data driving circuit may be disposed in the non-display area NAA. Several drivers 101 and 103 for driving the display area AA may be disposed in the non-display area NAA. For example, the drivers 101 and 103 may include a gate driver 101 and a data driver 103, but the present disclosure may not be limited thereto. The gate drivers 101 may be disposed in the non-display area NAA located on left and right sides of the display area AA.

The non-display area NAA may include a pad area PDA in which a plurality of pads electrically connected to the flexible printed circuit board 104 or the data driver 103 are disposed. The non-display area NAA may further include the link area LKA in which data link lines for electrically connecting the data lines DL of the display area AA with the data driver 103 or touch link lines for electrically connecting touch lines with the data driver 103 are disposed. For example, the link area LKA may be disposed between the display area AA and the pad area PDA, and the bendable area BDA may be disposed between the link area LKA and the pad area PDA.

The bendable area BDA of the display panel 200 may be bent such that a printed circuit board connected to the flexible printed circuit board 104 may be disposed on a rear surface of the display area AA of the display panel 200. As the bendable area BA of the display panel 200 is bent, the pad area PDA of the non-display area NAA may be located under the display area AA. Accordingly, a lower bezel area of the display device 1 recognized from a front surface of the display device 1 may be reduced.

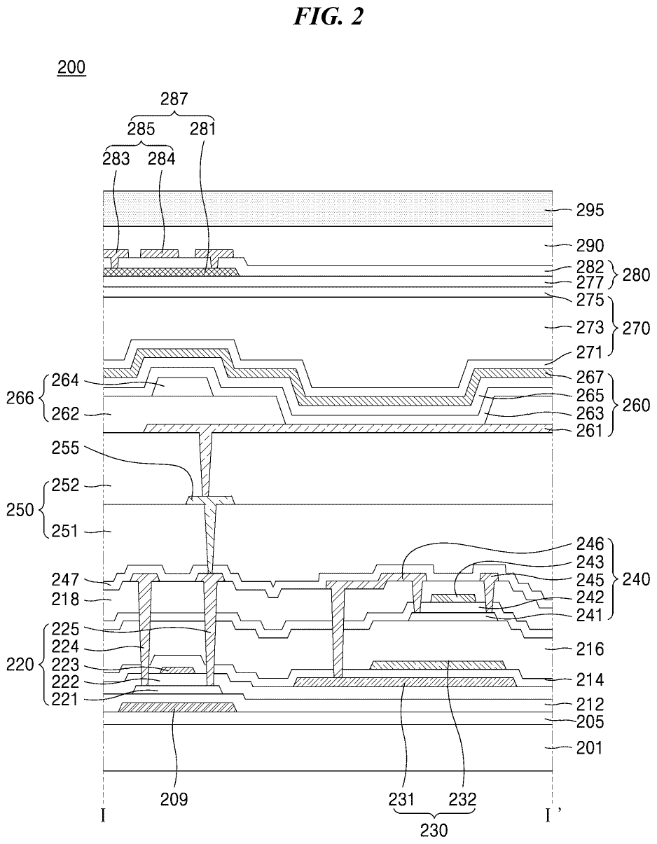

FIG. 2 is a cross-sectional view taken along a line I-I′ in FIG. 1. FIG. 2 schematically illustrates one example sub-pixel of in the display area of the display panel 200. Here, for convenience of description, one sub-pixel of the display panel 200 is illustrated, but the present disclosure is not limited thereto.

As shown in FIG. 2, the display panel 200 may include a pixel driving circuit including a plurality of transistors 220 and 240 disposed on a substrate 201, a light-emitting element 260, and a touch sensor 287.

One sub-pixel may include the light-emitting element 260 and the pixel driving circuit that applies a driving current to the light-emitting element 260. The pixel driving circuit may be disposed on the substrate 201, and the light-emitting element 260 may be disposed on the pixel driving circuit. The pixel driving circuit may include the plurality of transistors 220 and 240 and a storage capacitor 230. As an example, the plurality of transistors 220 and 240 may include a first transistor 220 and a second transistor 240.

The substrate 201 may be a flexible plastic substrate. Where the substrate 201 is the plastic film, it may include multiple layers of insulating materials. For example, the substrate 201 may include polyimide.

A first buffer layer 205 may be disposed on the substrate 201. The first buffer layer 205 may cover a surface of the substrate 201. For example, the first buffer layer 205 may cover an entire surface of the substrate 201. The first buffer layer 205 may reduce or prevent penetration of moisture, oxygen, or impurities through the substrate 201. The first buffer layer 205 may be composed of a single layer or multiple layers made of an inorganic insulating material, such as silicon oxide (SiOx) or silicon nitride (SiNx).

A light-shielding layer 209 may be disposed on the first buffer layer 205. The light-shielding layer 209 may prevent or block external light from being incident on the transistor. To this end, the light-shielding layer 209 may include an opaque metal material. A second buffer layer 212 may be disposed on the light-shielding layer 209. The second buffer layer 212 may protect the transistor from moisture, oxygen, or impurities. The second buffer layer 212 may be composed of a single layer or multiple layers made of an inorganic insulating material, such as silicon oxide (SiOx) or silicon nitride (SiNx), but may not be limited thereto. The second buffer layer 212 may entirely cover the surface of the substrate 201. For example, the second buffer layer 212 may extend to the link area LKA.

The first transistor 220 may be disposed on the second buffer layer 212. The first transistor 220 may include a first semiconductor layer 221, a first gate insulating layer 222, a first gate electrode 223, a first source electrode 224, and a first drain electrode 225. As an example, the first transistor 220 may be a driving transistor electrically connected to the light-emitting element 260.

The first semiconductor layer 221 may include a channel area and source/drain areas. An area of the first semiconductor layer 221 overlapping the first gate electrode 223 in a vertical direction may be the channel area. The source/drain areas may be disposed on both sides of the channel area, respectively. The first semiconductor layer 221 may be formed as one of an oxide semiconductor layer, a polysilicon semiconductor layer, and a low-temperature polysilicon semiconductor layer, or a combination thereof. The first semiconductor layer 221 may be disposed to overlap the light-shielding layer 209 in the vertical direction. The light-shielding layer 209 may prevent or block external light from being incident on the first semiconductor layer 221.

The first gate insulating layer 222 may be disposed between the first semiconductor layer 221 and the first gate electrode 223. The first gate insulating layer 222 may extend outward while covering the first semiconductor layer 221. The first gate insulating layer 222 may be composed of a single layer or a plurality of layers of an inorganic insulating material, such as silicon oxide (SiOx) or silicon nitride (SiNx).

The first gate electrode 223 may be disposed on the first gate insulating layer 222. A first interlayer insulating layer 214 may be disposed on the first gate electrode 223. The first interlayer insulating layer 214 may include a single layer or multiple layers made of an inorganic insulating material, such as silicon oxide (SiOx) or silicon nitride (SiNx). As an example, the first interlayer insulating layer 214 may extend to the link area LKA.

The first source electrode 224 and a first drain electrode 225 may be electrically connected to the first semiconductor layer 221.

The storage capacitor 230 may include a first storage electrode 231 and a second storage electrode 232. For example, the first storage electrode 231 may be located on the same layer as the first gate electrode 223. For example, the first storage electrode 231 may be made of the same material as the first gate electrode 223. The first storage electrode 231 may be disposed on the first gate insulating layer 222 at another location spaced apart from the first gate electrode 223. The second storage electrode 232 may be disposed on the first interlayer insulating layer 214 to overlap the first storage electrode 231 in the vertical direction.

The first storage electrode 231 and the second storage electrode 232 may each include a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the material is not limited thereto.

A second interlayer insulating layer 216 may be disposed on the second storage electrode 232. The second interlayer insulating layer 216 may include a single layer or multiple layers made of an inorganic insulating material, such as silicon oxide (SiOx) or silicon nitride (SiNx).

The second transistor 240 may be disposed on the second interlayer insulating layer 216 to be spaced apart from the first transistor 220. The second transistor 240 may be electrically connected to the first transistor 220. For example, the second transistor 240 may include a second semiconductor layer 241, a second gate insulating layer 242, a second gate electrode 243, a second source electrode 245, and a second drain electrode 246. For example, the second transistor 240 may be a switching transistor.

The second semiconductor layer 241 may include a channel area and source/drain areas. An area of the second semiconductor layer 241 overlapping the second gate electrode 243 in the vertical direction may be the channel area. The source/drain areas may be disposed on both sides of the channel area, respectively. The second semiconductor layer 241 may be formed of one of an oxide semiconductor layer, a polysilicon semiconductor layer, and a low-temperature polysilicon semiconductor layer, or a combination thereof. The second semiconductor layer 241 may be made of a material different from that of the first semiconductor layer 221 of the first transistor 220. For example, where the first semiconductor layer 221 is a polysilicon semiconductor layer, the second semiconductor layer 241 may be an oxide semiconductor layer. For example, the second semiconductor layer 241 may be disposed to overlap the storage capacitor 230 in the vertical direction. Accordingly, external light from outside of the substrate 201 may be blocked from being incident on the second semiconductor layer 241 may be blocked by the storage capacitor 230. Accordingly, characteristics of the second transistor 240 may be prevented or protected from being changed by external light.

The second gate insulating layer 242 may be disposed between the second semiconductor layer 241 and the second gate electrode 243. The second gate insulating layer 242 may extend outward while covering the second semiconductor layer 241. For example, the second gate insulating layer 242 may extend to the link area LKA. The second gate insulating layer 242 may be composed of a single layer or a plurality of layers made of an inorganic insulating material, such as silicon oxide (SiOx) or silicon nitride (SiNx).

The first gate electrode 223 or the second gate electrode 243 may include a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the material is not limited thereto.

A third interlayer insulating layer 218 may be disposed on the second gate electrode 243. The third interlayer insulating layer 218 may include an insulating material. For example, the third interlayer insulating layer 218 may include a single layer or multiple layers including an inorganic insulating material, such as silicon oxide, silicon nitride, and silicon oxynitride.

The first source electrode 224, the first drain electrode 225, the second source electrode 245, and the second drain electrode 246 may be disposed on the third interlayer insulating layer 218.

The first source electrode 224 and the first drain electrode 225 may pass through the third interlayer insulating layer 218, the second gate insulating layer 242, the second interlayer insulating layer 216, the first interlayer insulating layer 214, and the first gate insulating layer 222 to be in direct contact with and connected to the source/drain areas of the first semiconductor layer 221, respectively.

The second source electrode 245 and the second drain electrode 246 may pass through the third interlayer insulating layer 218 and the second gate insulating layer 242 to be in direct contact with and connected to the source/drain areas of the second semiconductor layer 241, respectively. The second drain electrode 246 of the second transistor 240 may be electrically connected to the storage capacitor 230. For example, a portion of the second drain electrode 246 may pass through the third interlayer insulating layer 218, the second gate insulating layer 242, the second interlayer insulating layer 216, and the first interlayer insulating layer 214 to be in direct contact with and connected to the first storage electrode 231 of the storage capacitor 230.

The first source electrode 224, the first drain electrode 225, the second source electrode 245, or the second drain electrode 246 may include a single layer or multiple layers made of one of molybdenum (Mo), aluminum (Al), chromium (Cr), gold (Au), titanium (Ti), nickel (Ni), neodymium (Nd), and copper (Cu), or an alloy thereof, but may not be limited thereto. As an example, the first source electrode 224 or the second drain electrode 225 may be a stacked structure of titanium/aluminum/titanium (Ti/Al/Ti).

A passivation layer 247 may be disposed on the first source electrode 224, the first drain electrode 225, the second source electrode 245, and/or the second drain electrode 246. The passivation layer 247 may extend outward. For example, the passivation layer 247 may extend to the link area LKA. The passivation layer 247 may include a single layer or multiple layers including an inorganic insulating material, such as silicon oxide, silicon nitride, and silicon oxynitride. The passivation layer 247 may protect the pixel driving circuit disposed thereunder.

A planarization layer 250 may be disposed on the passivation layer 247. The planarization layer 250 may planarize a step or steps resulting from the pixel driving circuit thereunder. The planarization layer 250 may be disposed in a multi-layered structure. The planarization layer 250 may include a first planarization layer 251 and a second planarization layer 252. For example, the planarization layer 250 may include an organic insulating material, such as polyimide or an acrylic resin. As an example, the first planarization layer 251 and the second planarization layer 252 may extend to the link area LKA.

A pixel contact electrode 255 may be disposed on the first planarization layer 151. The pixel contact electrode 255 may be in direct contact with the first drain electrode 225 of the first transistor 220 through the first planarization layer 251 and the passivation layer 247.

The light-emitting element 260 may be formed on the planarization layer 250. For example, the light-emitting element 260 may be disposed on the second planarization layer 252. The light-emitting element 260 may include a first electrode 261, a light-emitting layer 263, a second electrode 265, and a capping layer 267.

The light-emitting element 260 may be electrically connected to the pixel driving circuit via the first electrode 261. For example, the first electrode 261 may be in direct contact with the pixel contact electrode 255 through the second planarization layer 252. Accordingly, the first electrode 261 may be electrically connected to the first transistor 220 via the pixel contact electrode 255. The pixel contact electrode 255 may include a conductive material. For example, the pixel contact electrode 255 may include a metal material, such as aluminum (Al), chromium (Cr), copper (Cu), titanium (Ti), molybdenum (Mo), and tungsten (W). For example, the pixel contact electrode 255 may have a multi-layered structure of titanium/aluminum/titanium (Ti/Al/Ti).

The first electrode 261 may include a transparent conductive film. For example, the first electrode 261 may include indium tin oxide (ITO) or indium zinc oxide (IZO). Alternatively, the first electrode 261 may include a single or multi-layered structure including a reflective metal film made of one of silver (Ag), aluminum (Al), gold (Au), nickel (Ni), and chromium (Cr) or an alloy thereof. The first electrode 261 may also be referred to as an anode electrode or a pixel electrode.

A bank 262 may be disposed on the first electrode 261. The bank 262 may be disposed to cover an edge of the first electrode 261. A portion of the bank 262 may extend to the second planarization layer 252. A top surface of the first electrode 261 exposed without being covered by the bank 262 may be a light emissive area. The bank 262 may be made of an organic insulating material. The bank 262 may include, for example, photosensitive polyimide, photoacryl, or benzocyclobutene (BCB).

A spacer 264 may be further disposed on the bank 262. The spacer 264 may be disposed to prevent or suppress damage to the bank 262 and the first electrode 261 during a manufacturing process. The spacer 264 may be made of the same material as the bank 262. The bank 262 and the spacer 264 may overlap each other in the vertical direction to form a barrier layer 266. As an example, the barrier layer 266 may extend to the link area LKA in the non-display area NAA.

The light-emitting layer 263 may be disposed on the first electrode 261. Although not illustrated in detail, the light-emitting layer 263 may include a hole transport layer HTL, an organic light-emitting layer EML, an electron transport layer ETL, a hole blocking layer HBL, a hole injecting layer HIL, an electron blocking layer EBL, and an electron injecting layer EIL. The light-emitting layer 263 may have a multi-layered structure.

The second electrode 265 may be disposed on the light-emitting layer 263. The second electrode 265 may be commonly connected to the light-emitting layer 263 formed in all the pixels. Accordingly, the second electrode 265 may also be referred to as a cathode electrode or a common electrode. The second electrode 265 may include a transflective conductive material. For example, it may be made of a metal material, such as magnesium (Mg), silver (Ag), or an alloy (Ag—Mg) of silver (Ag) and magnesium (Mg). In another example, the second electrode 265 may include a transparent conductive film, such as indium-tin-oxide (ITO) or indium-zinc-oxide (IZO).

The capping layer 267 may be disposed on the second electrode 265. The capping layer 267 may correct optical characteristics by preventing light generated from the light-emitting layer 263 from being lost.

An encapsulation stack 270 may be disposed on the light-emitting element 260. The encapsulation stack 270 may protect the light-emitting element 260 from external oxygen or moisture. The encapsulation stack 270 may extend to the non-display area NAA outwardly of the display area AA while covering the display area AA. For example, the encapsulation stack 270 may extend to a partial area of the bezel area.

The encapsulation stack 270 may include a multi-layered structure in which a first encapsulation layer 271, a second encapsulation layer 273, and a third encapsulation layer 275 are disposed. The second encapsulation layer 273 may be a component disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may have a sufficient thickness to cover the first encapsulation layer 271 and to have a flat top surface. The second encapsulation layer 273 may prevent or block foreign substances from penetrating into the light-emitting element 260. The third encapsulation layer 275 may be disposed on the second encapsulation layer 273.

The first encapsulation layer 271 and the third encapsulation layer 275 may include an inorganic insulating material. For example, each of the first encapsulation layer 271 and the third encapsulation layer 275 may include at least one of silicon nitride (SiNx), silicon oxide (SiOx), and silicon oxynitride (SiON). The second encapsulation layer 273 may include an organic insulating material. For example, the second encapsulation layer 273 may include at least one of epoxy, polyimide, polyethylene, and acrylate.

A touch member may be disposed on the encapsulation stack 270. The touch member may include a touch buffer layer 277, a touch sensor 287, a touch interlayer insulating layer 282, and a touch protective layer 290.

The touch buffer layer 277 may be disposed on the third encapsulation layer 275. The touch buffer layer 277 may reduce stress between the encapsulation stack 270 and the touch sensor 287 layer to prevent or protect the encapsulation stack 270 and the light-emitting element 260 from being damaged. The touch buffer layer 277 may include an inorganic insulating material. For example, the touch buffer layer 277 may include silicon nitride (SiNx).

The touch sensor 287 may include a plurality of touch electrodes 285 and a bridge electrode 281. The plurality of touch electrodes 285 and the bridge electrode 281 may be disposed on different layers. For example, the bridge electrode 281 may be disposed on the touch buffer layer 277. The plurality of touch electrodes 285 may be disposed on the touch interlayer insulating layer 282. The plurality of touch electrodes 285 may include a first touch electrode 283 and a second touch electrode 284. The bridge electrode 281 may electrically connect adjacent portions of the first touch electrode 283 (or adjacent first touch electrodes 283) to each other. To this end, the first touch electrode 283 may be connected to the bridge electrode 281 through the touch interlayer insulating layer 282. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or multiple layers made of one of molybdenum (Mo), aluminum (Al), chromium (Cr), gold (Au), titanium (Ti), nickel (Ni), neodymium (Nd), and copper (Cu) or an alloy thereof. For example, the first touch electrode 283, the second touch electrode 284, or the bridge electrode 281 may be a stacked structure of titanium/aluminum/titanium (Ti/Al/Ti).

The touch buffer layer 277 and the touch interlayer insulating layer 282 may extend in a direction of the non-display area NAA. The touch buffer layer 277 and the touch interlayer insulating layer 282 may be in contact with each other in the vertical direction in the non-display area NAA to constitute a touch insulating structure 280. As an example, the touch insulating structure 280 may extend to the link area LKA.

The touch protective layer 290 may be disposed on the touch sensor 287. The touch protective layer 290 may prevent or suppress potential damage to the touch sensor 287 caused by external impact and moisture. The touch protective layer 290 may include an organic insulating material. For example, the touch protective layer 290 may be made of a photosensitive acrylic-based or polyimide-based organic material. The touch protective layer 290 may extend to the non-display area NAA. For example, the touch protective layer 290 may extend to the link area LKA.

An optical functional layer (or optical layer) 295 may be disposed on the touch protective layer 290. For example, the optical functional layer 295 may include a polarizing layer. The optical functional layer 295 may extend to the non-display area NAA. For example, the optical functional layer 295 may extend to a partial area of the link area LKA.

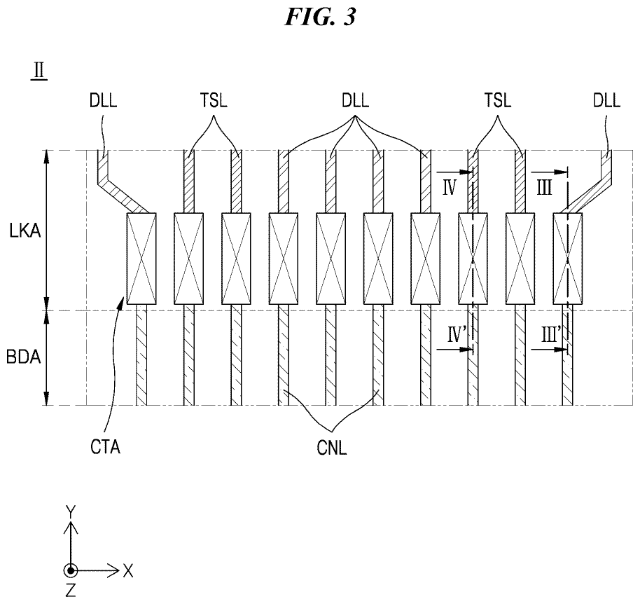

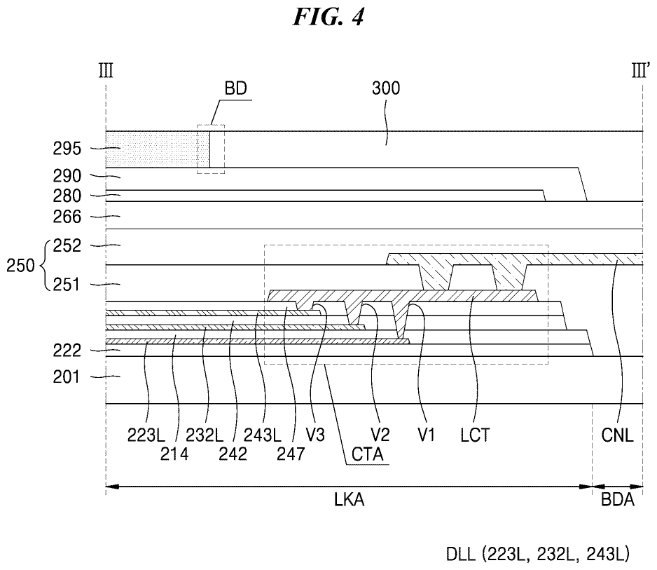

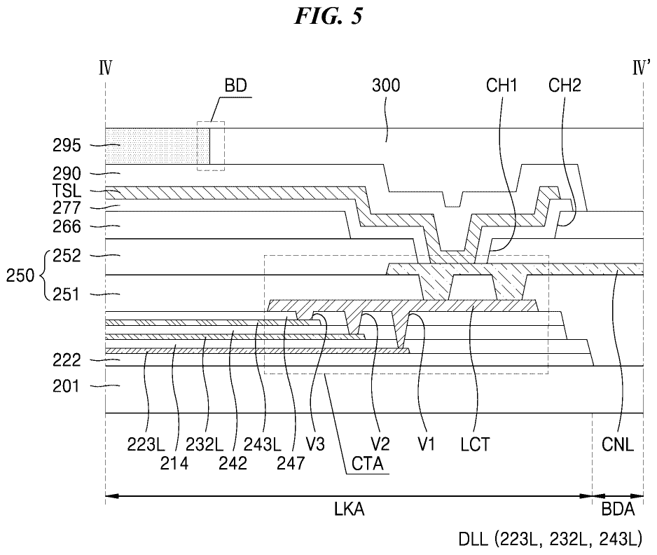

FIG. 3 is an enlarged view of an area II in FIG. 1. FIG. 4 is a cross-sectional view taken along a line III-III′ in FIG. 3. FIG. 5 is a cross-sectional view taken along a line IV-IV′ in FIG. 3. FIG. 3 is a plan view illustrating portions of the link area LKA and the bendable area BDA of the display panel 200. FIG. 4 is a diagram illustrating a portion of an area in which a data link line DLL for transmitting a signal for driving a pixel on the display area AA is disposed. FIG. 5 is a diagram illustrating a portion of an area in which a touch link line TSL for transmitting a signal to the touch sensor is disposed.

As shown in FIGS. 3 to 5, a plurality of signal link lines for transmitting signals to the display area AA may be disposed on the link area LKA. For example, the plurality of signal link lines may include a plurality of data link lines DLL and a plurality of touch link lines TSL. A plurality of connection lines CNL may be disposed on the link area LKA and extend to the bendable area BDA. The link area LKA may include contact areas CTA.

Each of the plurality of data link lines DLL and the plurality of touch link lines TSL may extend in the second direction (Y) in the link area LKA. The connection lines CNL may extend in the second direction (Y) in the bendable area BDA. The second direction (Y) may be a vertical direction or a height direction of the display panel 200. Each of the plurality of data link lines DLL and the plurality of touch link lines TSL may be connected to a corresponding one of the plurality of connection lines CNL in a contact area CTA located in the link area LKA. Some of the plurality of connection lines CNL may be connected respectively to the data link lines DLL, and the remainder thereof may be connected respectively to the touch link lines TSL. As an example, the plurality of connection lines CNL may extend to the pad area PDA via the bendable area BDA.

The data link lines DLL and the touch link lines TSL may be disposed on different layers. A touch link line TSL may be electrically connected to a data link line DLL in a contact area CTA. An area where a touch link line TSL and a data link line DLL are electrically connected to each other may be a jumping area.

As shown in FIGS. 4 and 5, the first gate insulating layer 222, the first interlayer insulating layer 214, the second gate insulating layer 242, and the passivation layer 247 may overlap each other in the vertical direction on the link area LKA of the substrate 201 to constitute an insulating stack structure. Each of the first gate insulating layer 222, the first interlayer insulating layer 214, the second gate insulating layer 242, and the passivation layer 247 may include an inorganic insulating material.

The first gate insulating layer 222, the first interlayer insulating layer 214, the second gate insulating layer 242, and the passivation layer 247, which may be made of an inorganic insulating material prone to cracking, may not be disposed in the bendable area BDA of the substrate 201. For example, the first planarization layer 251 and the second planarization layer 252 including an organic insulating material may be disposed in the bendable area BDA of the substrate 201. Because the first gate insulating layer 222, the first interlayer insulating layer 214, the second gate insulating layer 242, and the passivation layer 247 of the substrate 201 are disposed in the link area LKA, distal ends of these layers may define a boundary between the link area LKA and the bendable area BDA. For example, the distal ends of the first gate insulating layer 222 and the first interlayer insulating layer 214 disposed at a lowermost portion of the insulating stack structure may define the boundary between the bendable area BDA and the link area LKA.

The plurality of data link lines DLL may be disposed in the link area LKA of the substrate 201. As an example, each of the plurality of data link lines DLL may be disposed between respective two layers of the insulating stack structure. For example, the data link lines DLL may include a first data link line 223L, a second data link line 232L, and a third data link line 243L. As an example, the first data link line 223L, the second data link line 232L, and the third data link line 243L may be disposed to overlap each other in the vertical direction.

The first data link line 223L may be disposed between the first gate insulating layer 222 and the first interlayer insulating layer 214. The first data link line 223L may be made of the same material and formed in the same process as the first gate electrode 223. The second data link line 232L may be disposed on the first interlayer insulating layer 214. The second data link line 232L may be made of the same material and formed in the same process as the second storage electrode 232. The third data link line 243L may be disposed on the second gate insulating layer 242. The third data link line 243L may be made of the same material and formed in the same process as the second gate electrode 243.

A link contact electrode LCT may be disposed on the passivation layer 247 in the link area LKA. The link contact electrode LCT may be made of the same material and formed in the same process as the second source electrode 245 and the second drain electrode 246. The link contact electrode LCT may be electrically connected to the data link line DLL. For example, the link contact electrode LCT may be connected to the first data link line 223L via a first via electrode V1 passing through the passivation layer 247, the second gate insulating layer 242, and the first interlayer insulating layer 214. In addition, the link contact electrode LCT may be connected to the second data link line 232L via a second via electrode V2 passing through the passivation layer 247 and the second gate insulating layer 242. In addition, the link contact electrode LCT may be connected to the third data link line 243L via a third via electrode V3 passing through the passivation layer 247. The first via electrode V1, the second via electrode V2, and the third via electrode V3 may be integrally formed with the link contact electrode LCT.

The first planarization layer 251 covering the link contact electrode LCT may be disposed on the passivation layer 247. The first planarization layer 251 may be disposed in the link area LKA and the bendable area BDA of the substrate 201. For example, the first planarization layer 251 may be disposed in the bendable area BDA to be in direct contact with the substrate 201.

The link line CNL may be disposed on the first planarization layer 251. The link line CNL may be disposed in the link area LKA and the bendable area BDA. The connection line CNL may be made of the same material and formed in the same process as the pixel contact electrode 255 of the display area AA. As an example, the connection line CNL may have a multi-layered structure of titanium/aluminum/titanium (Ti/Al/Ti).

The connection line CNL may extend through the first planarization layer 251 in the contact area CTA to be connected to the link contact electrode LCT. Accordingly, the connection line CNL may be electrically connected to the data link line DLL via the link contact electrode LCT. As an example, a link contact electrode LCT may be disposed in a corresponding contact area CTA, and neighboring link contact electrodes LCT may be insulated from each other.

The second planarization layer 252 may be disposed on the connection line CNL. The second planarization layer 252 may be disposed in the link area LKA and the bendable area BDA of the substrate 201 while covering the connection line CNL. The second planarization layer 252 may planarize one or more steps resulting from the circuit elements thereunder.

The barrier layer 266 may be disposed on the second planarization layer 252 in the link area LKA and the bendable area BDA. The barrier layer 266 may be made of the same material and formed in the same process as the bank 262 and the spacer 264.

As shown in FIG. 4, on a portion where the data link line DLL is disposed, the touch insulating structure 280 may be disposed on the barrier layer 266. The touch insulating structure 280 may include the touch buffer layer 277 (see FIG. 2) and the touch interlayer insulating layer 282 (see FIG. 2). The touch insulating structure 280 may be covered with the touch protective layer 290. As an example, the touch protective layer 290 may be disposed in the link area LKA but may not be limited thereto.

As illustrated in FIG. 5, the touch link line TSL may be electrically connected to the data link line DLL via the connection line CNL. The touch link line TSL according to an example embodiment of the present disclosure may be made of the same material and formed in the same process as one of the plurality of touch electrodes 285.

For example, contact holes CH1 and CH2 may be formed in the second planarization layer 252 and the barrier layer 266, respectively. The contact holes CH1 and CH2 may include a first contact hole CH1 and a second contact hole CH2. The second contact hole CH2 may overlap the first contact hole CH1. The first contact hole CH1 may be formed to extend through the second planarization layer 252. The second contact hole CH2 may be formed to extend through the barrier layer 266. For example, the first contact hole CH1 may have a width relatively smaller than that of the second contact hole CH2. The first contact hole CH1 may expose a portion of an upper surface of the connection line CNL. Accordingly, the barrier layer 266 and the second planarization layer 252 may be implemented in a shape that descends in a stepwise manner in a downward direction toward the connection line CNL.

The touch buffer layer 277 may be disposed in the contact holes CH1 and CH2 and may expose a portion of the upper surface of the connection line CNL. The touch link line TSL may be disposed on the touch buffer layer 277. Accordingly, the touch link line TSL may extend along the touch buffer layer 277 disposed in the first contact hole CH1 and the second contact hole CH2 to be in direct contact with the connection line CNL. As an example, the touch link line TSL may have a stepped shape. The touch link line TSL may be covered with the touch protective layer 290.

The optical functional layer 295 and a bending protective layer 300 may be disposed on the touch protective layer 290 in the link area LKA. The optical functional layer 295 may include a polarizing layer. The bending protective layer 300 may include a hydrophobic insulating material. Accordingly, moisture may be prevented from penetrating into the lower structure.

The optical functional layer 295 may be disposed in the link area LKA. The bending protective layer 300 may be disposed in the link area LKA and the bendable area BDA. One side of the bending protective layer 300 may be in contact with a distal end of the optical functional layer 295. Accordingly, a boundary area BD where a distal end of the bending protective layer 300 and the distal end of the optical functional layer 295 are in contact with each other may be located in the link area LKA.

The boundary area BD between the bending protective layer 300 and the optical functional layer 295 may be vulnerable to the moisture penetration. The touch protective layer 290 may include an organic insulating material and may be disposed to continuously extend from the link area LKA to the bendable area BDA. Accordingly, the touch protective layer 290 may become a moisture permeable path through which moisture permeated into the boundary area BD may move to the connection line CNL thereunder. For example, moisture (H₂O) permeated via the boundary area BD between the bending protective layer 300 and the optical functional layer 295 may move to the bendable area BDA along the touch protective layer 290 and may come into contact with the connection line CNL via the barrier layer 266 and the second planarization layer 252.

In addition, moisture (H₂O) may move along the touch protective layer 290 in contact with the touch link line TSL and come into contact with the connection line CNL in a portion where the touch link line TSL is disposed.

When a voltage is applied in the state in which the connection line CNL is in contact with moisture and moisture is permeated thereinto, corrosion may occur in the connection line CNL due to an electric field and moisture. For example, the connection line CNL may have a multi-layered structure of titanium/aluminum/titanium (Ti/Al/Ti).

When the voltage is applied to the multi-layered structure of titanium/aluminum/titanium (Ti/Al/Ti) in the state in which moisture is permeated thereinto and the device is driven at a high temperature, the corrosion may occur because of a galvanic reaction. The corrosion caused by the galvanic reaction is a corrosion that occurs when two metals with different materials are in contact with moisture. In addition, when the corrosion occurs by a reaction between aluminum (Al) and moisture (H₂O), hydrogen (H₂) gas and aluminum oxide (Al₂O₃) may be generated during the corrosion process. Hydrogen (H₂) gas may promote hydroxylation of titanium (Ti) to change a lattice structure into titanium hydroxide (TiHx) and increase brittleness. The brittleness may be understood as a phenomenon in which a material may be suddenly destroyed with little plastic deformation when it is subjected to an impact within an elastic limit thereof.

As the brittleness increases in the connection line CNL including the multi-layered structure of titanium/aluminum/titanium (Ti/Al/Ti), a crack in the connection line CNL may be caused in the bendable area BDA having a high tensile stress.

Accordingly, in another example embodiment of the present disclosure, the data link line DLL or the touch link line TSL may be prevented or protected from being corroded by moisture permeated into the boundary area BD where the bending protective layer 300 and the optical functional layer 295 are in contact with each other.

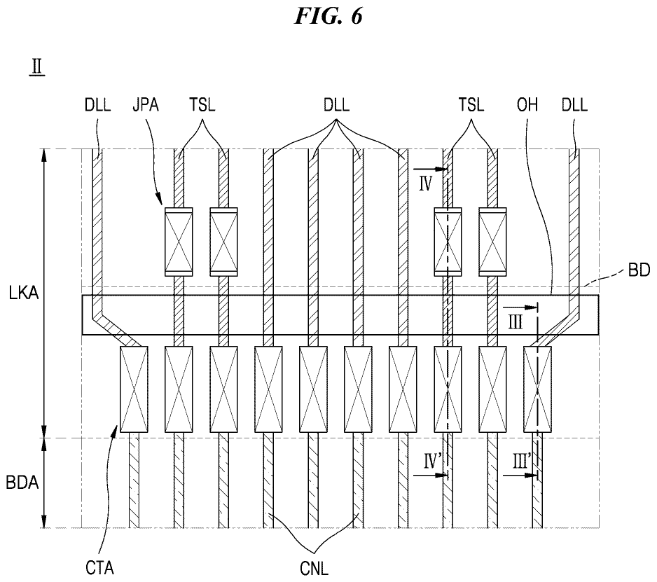

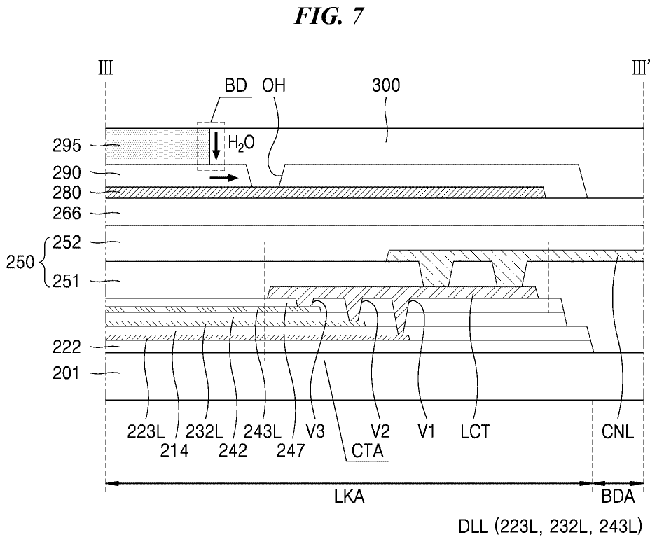

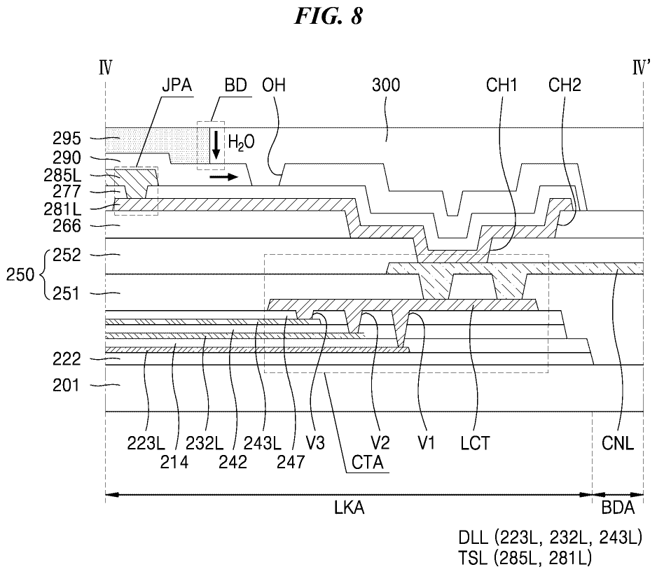

FIG. 6 is a plan view according to other example embodiments of the present disclosure. FIGS. 7 and 8 are cross-sectional views according to another example embodiment of the present disclosure. For example, FIG. 6 is an enlarged view of an area II in FIG. 1. FIG. 7 is a cross-sectional view taken along a line III-III′ in FIG. 6. FIG. 8 is a cross-sectional view taken along a line IV-IV′ in FIG. 6. In FIGS. 6 to 8, the same components as those in FIGS. 3 to 5 may be assigned with the same reference numerals. Accordingly, redundant descriptions will be omitted or briefly made, and parts that are different will be described.

As shown in FIGS. 6 to 8, the touch protective layer 290 of the link area LKA may include an opening OH. The opening OH may extend in a direction, for example, the first direction (X), intersecting the data link lines DLL and the touch link lines TSL which are disposed in the second direction (Y). The opening OH may extend in a continuous line shape.

The opening OH may be disposed outwardly of the boundary area BD where the distal end of the bending protective layer 300 and the distal end of the optical functional layer (or optical layer) 295 are in contact with each other. For example, the opening OH may be defined outwardly of the distal end of the optical functional layer 295. For example, the opening OH may be disposed inwardly of the distal end of the connection line CNL.

The opening OH may extend through the touch protective layer 290 to expose a portion of a surface of the touch insulating structure 280. Accordingly, the opening OH may prevent the touch protective layer 290 from continuously extending to the bendable area BDA. For example, the opening OH may define at least one broken region or discontinuous part of the touch protective layer 290. The touch insulating structure 280 may include a hydrophobic inorganic insulating material, such as silicon nitride.

Accordingly, even if moisture (H₂O) penetrates via the boundary area BD between the bending protective layer 300 and the optical functional layer 295, the moisture permeation path may be disconnected by the opening OH. Accordingly, because the connection line CNL may be prevented or protected from being exposed to moisture (H₂O), the crack or the damage of the connection line CNL potentially resulting from the corrosion may be prevented or suppressed. Therefore, because the crack of the connection line CNL may be prevented or suppressed from occurring in the bendable area BDA having a high tensile stress, an occurrence of an operation failure of the display device potentially resulting from the damage of the line may be prevented or suppressed. Accordingly, product reliability of the display device may be improved.

In addition, as shown in FIGS. 6 and 8, the touch link line TSL in the link area LKA may include a jumping area JPA. The jumping area JPA may be disposed inwardly toward the display area AA from the boundary area BD where the distal end of the bending protective layer 300 and the distal end of the optical functional layer 295 are in contact with each other. The touch link lines TSL may include a first touch link line 285L and a second touch link line 281L. The first touch link line 285L and the second touch link line 281L may be disposed on different layers. For example, the first touch link line 285L may be disposed on the touch buffer layer 277, and the second touch link line 281L may be disposed under the first touch link line 285L. For example, the second touch link line 281L may be disposed on the barrier layer 266 below the touch buffer layer 277 and may extend in a direction toward the bendable area BDA.

The first touch link line 285L may pass through the touch buffer layer 277 in the jumping area JPA to be in contact with the second touch link line 281L.

The first touch link line 285L may extend from the display area AA to the link area LKA. For example, the first touch link line 285L may be made of the same material and formed in the same process as one of the touch electrodes 285 of the display area AA. The second touch link line 281L may be made of the same material and formed in the same process as the bridge electrode 281 of the display area AA.

The second touch link line 281L may extend to the contact area CTA and may be connected to the connection line CNL. The contact holes CH1 and CH2 may be defined in the second planarization layer 252 and the barrier layer 266, respectively. The contact holes CH1 and CH2 may include the first contact hole CH1 and the second contact hole CH2. The second contact hole CH2 may overlap the first contact hole CH1. The first contact hole CH1 may be formed to extend through the second planarization layer 252. The second contact hole CH2 may be formed to extend through the barrier layer 266. For example, the first contact hole CH1 may have the width relatively smaller than that of the second contact hole CH2. The first contact hole CH1 may expose the portion of an upper surface of the connection line CNL. Accordingly, the barrier layer 266 and the second planarization layer 252 may be implemented in the shape that descends in the stepwise manner in the downward direction toward the connection line CNL.

The second contact hole CH1 may expose a portion of the upper surface of the connection line CNL. The second touch link line 281L may extend along the barrier layer 266, the second contact hole CH2, and the first contact hole CH1 to be in direct contact with the connection line CNL. As an example, the second touch link line 281L may have a stepped shape.

The touch link line TSL may include the jumping area JPA located more inwardly toward the display area AA than the opening OH is with respect to the distal end of the bending protective layer 300, and the second touch link line 281L may be disposed beneath the touch buffer layer 277. Because the second touch link line 281L is disposed beneath the touch buffer layer 277, the touch buffer layer 277 may function as a protective film and prevent or suppress damage to the second touch link line 281L. For example, because the touch buffer layer 277 including the inorganic insulating material is disposed to cover the second touch link line 281L, potential damage by a developing solution may be prevented or suppressed in a process of patterning the touch protective layer 290 to define the opening OH.

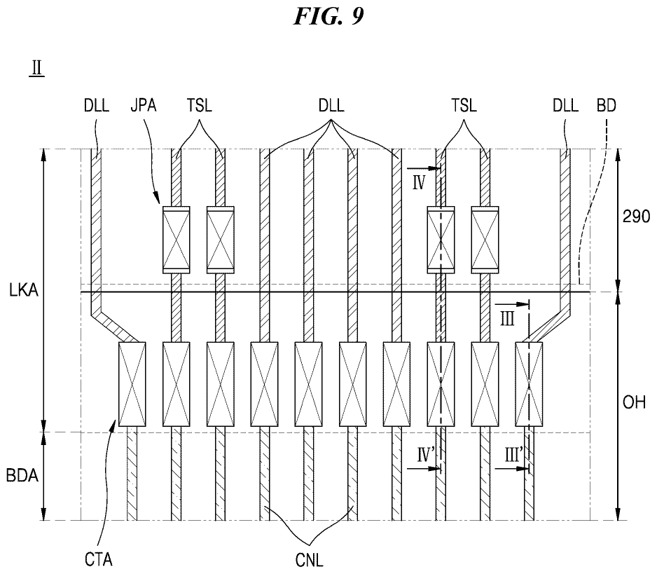

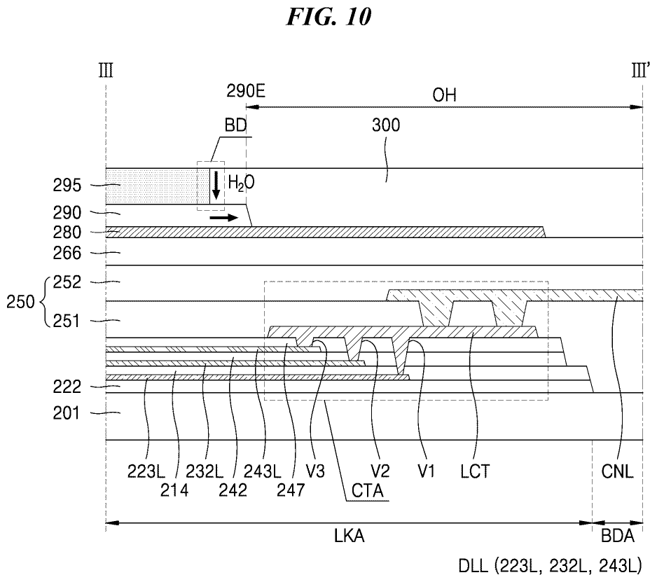

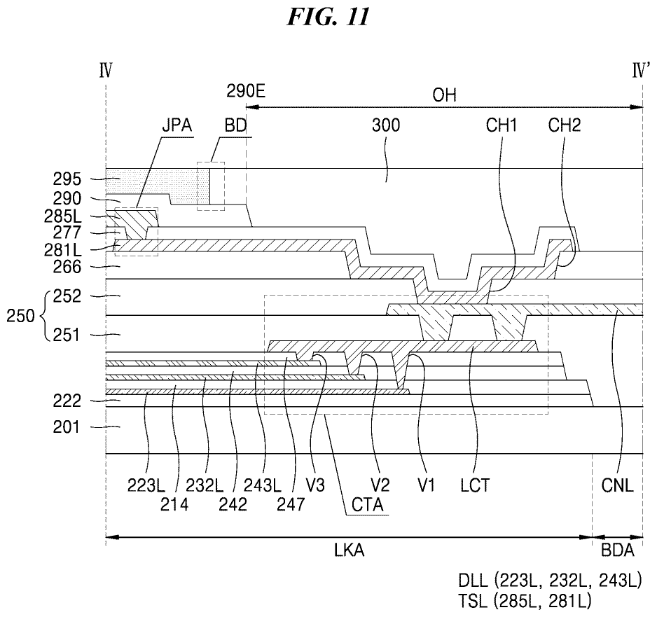

FIGS. 9 to 11 are cross-sectional views according to still another example embodiment of the present disclosure. For example, FIG. 9 is a plan view according to still another example embodiment of the present disclosure. FIG. 10 is another example cross-sectional view taken along a line III-III′ in the example embodiment of FIG. 9. FIG. 11 is another example cross-sectional view taken along a line IV-IV′ in the example embodiment of FIG. 9. FIG. 10 illustrates the data link line DLL disposed in the link area LKA, and FIG. 11 illustrates the touch link line TSL disposed in the link area LKA. As FIGS. 10 and 11 include the same components as those in FIGS. 7 and 8 except for a shape of the touch protective layer 290, redundant descriptions will be omitted or briefly made, and parts that are different will be described. Like reference numerals may refer to like components.

As shown in FIGS. 10 and 11 together with FIG. 9, in the portion in which the data link line DLL is disposed in the link area LKA, a length of the touch protective layer 290 extending in the direction toward the bendable area BDA may be reduced. As an example, the jumping area JPA may be disposed on the touch link line TSL in the link area LKA. The jumping area JPA may be disposed inwardly toward the display area AA from the distal end of the bending protective layer 300. Accordingly, the jumping area JPA may be disposed inwardly toward the display area AA from the boundary area BD where the distal end of the bending protective layer 300 and the distal end of the optical functional layer 295 are in contact with each other.

The touch link line TSL may include the first touch link line 285L extending from the display area AA to the jumping area JPA, and include the second touch link line 281L extending from the jumping area JPA to the link area LKA and electrically connected to the connection line CNL.

In the link area LKA where the data link line DLL is disposed, a length by which the touch protective layer 290 extends in the direction of the bendable area BDA may be reduced. In this case, the touch protective layer 290 may expose a surface of the touch insulating structure 280 (for example, the touch buffer layer 277). Accordingly, a region in which the surface of the touch insulating structure 280 is exposed from the outermost distal end 290E of the touch protective layer 290 may be referred to as an opening OH. The touch insulating structure 280 (e.g., the touch buffer layer 277) may cover an exposed surface of the second touch link line 281L extending from the jumping area JPA in the direction of the bendable area BDA. For example, the touch insulating structure 280 may be in direct contact with and cover a top surface and a distal end of the second touch link line 281L. In addition, the touch insulating structure 280 may be disposed to extend from the area where the data link line DLL is disposed at least to the contact area CTA where the connection line CNL disposed. Accordingly, the length of the touch protective layer 290 may be reduced.

As the jumping area JPA of the touch link line TSL is disposed in an area closer to the display area AA than the boundary area BD is, a length of the touch protective layer 290 extending from the boundary area BD in the direction toward the link area LKA may be reduced. For example, an outermost distal end of the touch protective layer 290 may be disposed at a location closer to the boundary area BD than the nearest distal end of the link contact electrode LCT.

Accordingly, a length of the touch protective layer 290 disposed in the link area LKA may be reduced, and an area of the touch protective layer 290 disposed in the link area LKA may be reduced or eliminated. As a result, the touch protective layer 290 can be prevented or suppressed from becoming the moisture penetration path of the outermost portion of the display area AA and potentially causing a crack, thereby improving driving reliability of the display device.

Hereinafter, a structure capable of preventing or suppressing the phenomenon in which the touch protective layer 290 becomes the moisture permeable path on the touch link line TSL will be described.

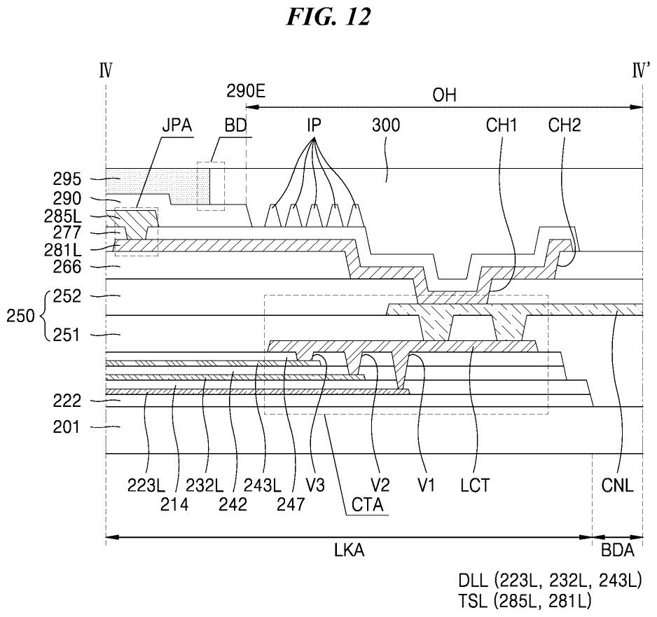

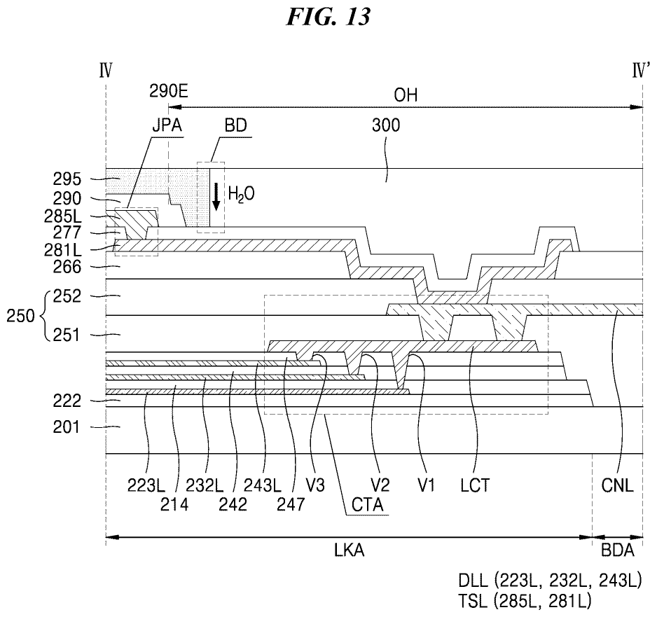

FIGS. 12 and 13 are cross-sectional views according to yet other example embodiments of the present disclosure. For example, FIGS. 12 and 13 are additional example cross-sectional views taken along a line IV-IV′ in the example embodiment of FIG. 9. FIGS. 12 and 13 illustrate the touch link line TSL disposed in the link area LKA. Because FIGS. 12 and 13 include the same components as those in FIG. 8 except for the shape of the touch protective layer 290, redundant descriptions will be omitted or briefly made, and parts that are different will be described. Like reference numerals may refer to like components.

As shown in FIG. 12, the touch protective layer 290 of the link area LKA may include the opening OH. The opening OH may include a region in which the surface of the touch buffer layer 277 and the surface of the barrier layer 266 are exposed from the outermost distal end 290E of the touch protective layer 290. The opening OH may be formed outwardly toward the bendable area BDA from the boundary area BD between the bending protective layer 300 and the optical functional layer (or optical layer) 295. In a plan view, as shown in FIG. 9, the opening OH may extend in the direction, for example, in the first direction (X), intersecting the data link lines DL and the touch link lines TSL disposed in the second direction (Y), but may not be limited thereto. As illustrated in FIG. 9, the opening OH may extend in the continuous line shape in the first direction (X) and the second direction (Y) in a plan view, but may not be limited thereto.

A plurality of isolated patterns IP may be disposed on the touch buffer layer 277 in the opening OH. The plurality of isolated patterns IP may be disposed to be spaced apart from each other in an outward direction from the opening OH toward the bendable area BDA. The plurality of isolated patterns IP may be made of the same material and formed in the same process as the touch protective layer 290. A top surface and both side surfaces of each isolation pattern IP may be in direct contact with the bending protective layer 300. A contact area of the bending protective layer 300 with the underlying layer(s), including the touch protective layer 290, may be increased by the isolation patterns IP. Accordingly, an adhesive strength of the bending protective layer 300 in the link area LKA may be improved.

In addition, the jumping area JPA may be disposed inwardly toward the display area from the boundary area BD between the bending protective layer 300 and the optical functional layer 295. For example, the jumping area JPA may be disposed in the non-display area NAA at a location closer to the display area AA. Accordingly, the second touch link line 281L among the touch link lines TSL may be in direct contact with and be covered by the touch buffer layer 277 including the inorganic insulating material. Accordingly, the touch link line TSL may be prevented or protected from being in contact with the organic insulating material. Accordingly, the touch link line TSL may be prevented or protected from potentially being corroded by being in contact with moisture. Therefore, a defect rate of the display device resulting from the possible corrosion of the connection lines or the signal lines may be lowered, and the production energy required for further production of the display device may be reduced, thereby reducing emission of greenhouse gas.

FIG. 13 illustrates another example cross-sectional view taken along a line IV-IV′ in an example embodiment of FIG. 9. As shown in FIG. 13, the jumping area JPA may be disposed on the touch link line TSL in the link area LKA. The jumping area JPA may be disposed inwardly toward the display area AA from the distal end of the bending protective layer 300. For example, the jumping area JPA may be disposed inwardly toward the display area AA from the boundary area BD where the distal end of the bending protective layer 300 and the distal end of the optical functional layer (or optical layer) 295 are in contact with each other.

The touch link line TSL may include the first touch link line 285L and the second touch link line 281L extending from the jumping area JPA and electrically connected to the connection line CNL.

The touch protective layer 290 may cover the top surface and the distal end of the first touch link line 285L. An outermost distal end 290E of the touch protective layer 290 may be disposed inwardly toward the display area AA from the boundary area BD between the optical functional layer 295 and the bending protective layer 300. For example, the outermost distal end 290E of the touch protective layer 290 may be in direct contact with and be covered by the optical functional layer 295. Accordingly, the touch protective layer 290 including the organic insulating material may be prevented or blocked from being exposed in the boundary area BD.

Accordingly, even when moisture (H₂O) penetrates into the boundary area BD between the optical functional layer 295 and the bending protective layer 300, moisture may be blocked from flowing in a direction toward the connection line CNL by the touch buffer layer 277 including the inorganic material. Therefore, the touch protective layer 290 can be prevented or blocked from becoming the moisture penetration path of the outermost portion of the display area AA and potentially causing a crack, thereby improving driving reliability of the display device.

A display device according to various example embodiments of the present disclosure may be described as follows.

A display device according to an embodiment of the present disclosure includes a substrate including a display area and a non-display area outside the display area, the non-display area including a link area and a bendable area; a plurality of signal link lines in the link area of the substrate, the link area being between the display area and the bendable area; a plurality of connection lines electrically connected respectively to the plurality of signal link lines in the link area and extending to the bendable area; an organic insulating layer above and spaced apart from the plurality of connection lines; an optical layer over the organic insulating layer in the link area; and a bending protective layer in contact with an end of the optical layer in the link area and extending to the bendable area, wherein the organic insulating layer includes a broken region in the link area.

According to various embodiments of the present disclosure, the broken region of the organic insulating layer may be disposed closer to the bendable area than a boundary between the optical layer and the bending protective layer is.

According to various embodiments of the present disclosure, the organic insulating layer may include an opening, and the broken region may include at least one side surface of the opening. The opening may be disposed closer to the bendable area than a boundary between the optical layer and the bending protective layer is.

According to various embodiments of the present disclosure, the opening may be disposed in the link area and, in a plan view, may have a continuous line shape extending in a direction intersecting the plurality of signal link lines.

According to various embodiments of the present disclosure, the plurality of signal link lines may include a data link line connected to and disposed under a first connection line among the plurality of connection lines, and a touch link line connected to and disposed on the first connection line.

According to various embodiments of the present disclosure, the display device may further include a link contact electrode disposed and connected between the first connection line and the data link line.

According to various embodiments of the present disclosure, the data link line may include a first data link line, a second data link line overlapping the first data link line in a vertical direction, and a third data link line overlapping the second data link line in the vertical direction, wherein each of the first data link line, the second data link line, and the third data link line may be electrically connected to the link contact electrode.

According to various embodiments of the present disclosure, the plurality of signal link lines may further include another data link line spaced apart from the data link line and connected to a second connection line, among the plurality of connection lines, and the second connection line may be spaced apart from the first connection line in a plan view.

According to various embodiments of the present disclosure, the organic insulating layer may further include a plurality of isolated patterns spaced apart from the broken region, and a top surface and side surfaces of each of the plurality of isolated patterns may be in contact with the bending protective layer.

According to various embodiments of the present disclosure, the broken region of the organic insulating layer may include a distal end of the organic insulating layer and may be disposed closer to the display area than a distal end of the optical layer is, and the optical layer may cover the distal end of the organic insulating layer.

According to various embodiments of the present disclosure, the plurality of signal lines may include a first touch link line, and a second touch link line disposed under and electrically connected to the first touch link line in a jumping area in the link area, wherein the second touch link line may be electrically connected to one of the plurality of connection lines.

According to various embodiments of the present disclosure, the display device may further include a touch insulating layer between the first touch link line and the second touch link line, wherein the first touch link line may extend through the touch insulating layer to be connected to the second touch link line in the jumping area, and wherein the jumping area may be disposed farther away from the bending area than a distal end of the optical layer.

In another aspect, a display device according to an embodiment of the present disclosure includes a substrate including a display area including a pixel, and a non-display area outside the display area, the non-display area including a bendable area and including a link area between the display area and the bendable area; a data link line in the link area of the substrate for transmitting a signal or voltage to the pixel in the display area; a first connection line electrically connected to the data link line in the link area and extending to the bendable area; an inorganic insulating layer on the first connection line; an organic insulating layer on the inorganic insulating layer and spaced apart from the first connection line; and an optical layer over the organic insulating layer and having a distal end in the link area, wherein the organic insulating layer includes a discontinuous part in the link area.

According to various embodiments of the present disclosure, the display device may further include a bending protective layer over the inorganic insulating layer and in contact with the distal end of the optical layer in the link area, the bending protective layer extending to the bendable area. The discontinuous part of the organic insulating layer may be a distal end of the organic insulating layer or a side surface of an opening in the organic insulating layer, and the discontinuous part of the organic insulating layer may be disposed closer to the bendable area than the distal end of the optical layer is.

According to various embodiments of the present disclosure, the display device may further include a first link contact electrode connected between the first connection line and the data link line. In a plan view, a distal end of the first link contact electrode nearest the distal end of the optical layer may be farther away from the distal end of the optical layer than the discontinuous part of the organic insulating layer is.

According to various embodiments of the present disclosure, the display device may further include a touch electrode in the display area, a touch link line in the link area electrically connected to the touch electrode, and a second connection line disposed under and electrically connected to the touch link line in the link area, the second connection line extending to the bendable area, wherein the second connection line may be spaced apart from the first connection line in a plan view.

According to various embodiments of the present disclosure, the display device may further include a bending protective layer over the touch link line and in contact with the distal end of the optical layer in the link area, the bending protecting layer extending to the bendable area. The discontinuous part of the organic insulating layer may be a distal end of the organic insulating layer or a side surface of an opening in the organic insulating layer, and the discontinuous part of the organic insulating layer may be disposed closer to the display area than the second connection line is.

According to various embodiments of the present disclosure, the organic insulating layer may further include a plurality of isolated patterns spaced apart from the discontinuous part, and a top surface and side surfaces of each of the plurality of isolated patterns may be in contact with the bending protective layer.

According to various embodiments of the present disclosure, the discontinuous part of the organic insulating layer may be the distal end of the organic insulating layer and may be disposed closer to the display area than the distal end of the optical layer is. The optical layer may cover the distal end of the organic insulating layer.

According to various embodiments of the present disclosure, the touch link line may include a first touch link line under the organic insulating layer and having a distal end covered by the organic insulating layer, a touch insulating layer under the first touch link line, and a second touch link line under the touch insulating layer and connected to the second connection line. The first touch link line may be connected to the second touch link line via a contact hole in the touch insulating layer in the link area, and the contact hole may be disposed farther away from the bending area than the distal end of the optical layer.

Although some example embodiments of the present disclosure have been described above with reference to the accompanying drawings, the present disclosure may not be limited to these example embodiments and may be implemented in various different forms. Those of ordinary skill in the technical field to which the present disclosure belongs will be able to appreciate that the present disclosure may be implemented in other specific forms without departing from the technical idea, spirit, or features of the present disclosure. Therefore, it should be understood that the example embodiments as described above are not restrictive but are illustrative in all respects.

What is claimed is:

1. A display device, comprising:
a substrate including a display area and a non-display area outside the display area, the non-display area including a link area and a bendable area;
a plurality of signal link lines in the link area of the substrate, the link area being between the display area and the bendable area;
a plurality of connection lines electrically connected respectively to the plurality of signal link lines in the link area and extending to the bendable area;
an organic insulating layer above and spaced apart from the plurality of connection lines;
an optical layer over the organic insulating layer in the link area; and
a bending protective layer in contact with an end of the optical layer in the link area and extending to the bendable area,
wherein the organic insulating layer includes a broken region in the link area.

2. The display device of claim 1, wherein the broken region of the organic insulating layer is disposed closer to the bendable area than a boundary between the optical layer and the bending protective layer is.

3. The display device of claim 1, wherein:
the organic insulating layer includes an opening, and the broken region includes at least one side surface of the opening; and
the opening is disposed closer to the bendable area than a boundary between the optical layer and the bending protective layer is.

4. The display device of claim 3, wherein the opening is disposed in the link area and, in a plan view, has a continuous line shape extending in a direction intersecting the plurality of signal link lines.

5. The display device of claim 1, wherein the plurality of signal link lines include:
a data link line connected to and disposed under a first connection line among the plurality of connection lines; and
a touch link line connected to and disposed on the first connection line.

6. The display device of claim 5, further comprising a link contact electrode disposed and connected between the first connection line and the data link line.

7. The display device of claim 6, wherein the data link line includes:
a first data link line;
a second data link line overlapping the first data link line in a vertical direction; and
a third data link line overlapping the second data link line in the vertical direction,
wherein each of the first data link line, the second data link line, and the third data link line is electrically connected to the link contact electrode.

8. The display device of claim 5, wherein the plurality of signal link lines further include another data link line spaced apart from the data link line and connected to a second connection line, among the plurality of connection lines, and the second connection line is spaced apart from the first connection line in a plan view.

9. The display device of claim 1, wherein:
the organic insulating layer further includes a plurality of isolated patterns spaced apart from the broken region; and
a top surface and side surfaces of each of the plurality of isolated patterns are in contact with the bending protective layer.

10. The display device of claim 1, wherein:
the broken region of the organic insulating layer includes a distal end of the organic insulating layer and is disposed closer to the display area than a distal end of the optical layer is; and
the optical layer covers the distal end of the organic insulating layer.

11. The display device of claim 1, wherein the plurality of signal link lines include:
a first touch link line; and
a second touch link line disposed under and electrically connected to the first touch link line in a jumping area in the link area,
wherein the second touch link line is electrically connected to one of the plurality of connection lines.

12. The display device of claim 11, further comprising:
a touch insulating layer between the first touch link line and the second touch link line,
wherein the first touch link line extends through the touch insulating layer to be connected to the second touch link line in the jumping area, and
wherein the jumping area is disposed farther away from the bending area than a distal end of the optical layer.

13. A display device, comprising:
a substrate including:
a display area including a pixel; and
a non-display area outside the display area, the non-display area including a bendable area and including a link area between the display area and the bendable area;
a data link line in the link area of the substrate for transmitting a signal or voltage to the pixel in the display area;
a first connection line electrically connected to the data link line in the link area and extending to the bendable area;
an inorganic insulating layer on the first connection line;
an organic insulating layer on the inorganic insulating layer and spaced apart from the first connection line; and
an optical layer over the organic insulating layer and having a distal end in the link area,
wherein the organic insulating layer includes a discontinuous part in the link area.

14. The display device of claim 13, further comprising:
a bending protective layer over the inorganic insulating layer and in contact with the distal end of the optical layer in the link area, the bending protective layer extending to the bendable area,
wherein the discontinuous part of the organic insulating layer is a distal end of the organic insulating layer or a side surface of an opening in the organic insulating layer, the discontinuous part of the organic insulating layer being disposed closer to the bendable area than the distal end of the optical layer is.

15. The display device of claim 13, further comprising a first link contact electrode connected between the first connection line and the data link line,
wherein, in a plan view, a distal end of the first link contact electrode nearest the distal end of the optical layer is farther away from the distal end of the optical layer than the discontinuous part of the organic insulating layer is.

16. The display device of claim 13, further comprising:
a touch electrode in the display area;
a touch link line in the link area electrically connected to the touch electrode; and
a second connection line disposed under and electrically connected to the touch link line in the link area, the second connection line extending to the bendable area,
wherein the second connection line is spaced apart from the first connection line in a plan view.

17. The display device of claim 16, further comprising:
a bending protective layer over the touch link line and in contact with the distal end of the optical layer in the link area, the bending protecting layer extending to the bendable area,
wherein the discontinuous part of the organic insulating layer is a distal end of the organic insulating layer or a side surface of an opening in the organic insulating layer, and the discontinuous part of the organic insulating layer is disposed closer to the display area than the second connection line is.

18. The display device of claim 17, wherein:
the organic insulating layer further includes a plurality of isolated patterns spaced apart from the discontinuous part; and
a top surface and side surfaces of each of the plurality of isolated patterns are in contact with the bending protective layer.

19. The display device of claim 17, wherein:
the discontinuous part of the organic insulating layer is the distal end of the organic insulating layer and is disposed closer to the display area than the distal end of the optical layer is; and
the optical layer covers the distal end of the organic insulating layer.

20. The display device of claim 17, wherein the touch link line includes:
a first touch link line under the organic insulating layer and having a distal end covered by the organic insulating layer;
a touch insulating layer under the first touch link line; and
a second touch link line under the touch insulating layer and connected to the second connection line,
wherein the first touch link line is connected to the second touch link line via a contact hole in the touch insulating layer in the link area, and
wherein the contact hole is disposed farther away from the bending area than the distal end of the optical layer.
